(19) United States
(12) Patent Application Publication
(10) Pub. No.: US 2022/0137209 A1
(43) Pub. Date: May 5, 2022

(54) SWITCHABLE REFLECTIVE PHASE SHIFTER FOR MILLIMETER WAVE APPLICATIONS

(71) Applicant: Metawave Corporation, Carlsbad, CA (US)

(72) Inventor: Raul Inocencio ALIDIO, Palo Alto, CA (US)

(21) Appl. No.: 17/433,194

(22) PCT Filed: Feb. 26, 2020
(86) PCT No.: PCT/US2020/019854

§ 371 Date: Aug. 23, 2021

Related U.S. Application Data
(60) Provisional application No. 62/810,950, filed on Feb. 26, 2019.

(51) Int. Cl. G01S 13/931; H01Q 3/26

(52) U.S. Cl. CPC G01S 13/931; H01Q 3/2694

(57) ABSTRACT

Examples disclosed herein relate to a switchable reflective phase shifter for millimeter wave applications. The switchable reflective phase shifter has a switchable phase shift network with a plurality of switches to activate a plurality of phase subranges in response to a plurality of bias voltages provided by a control module, and a reflective phase shifter to generate phase shifts in a given phase subrange activated by a given switch in the plurality of switches.

### CROSS-REFERENCE TO RELATED APPLICATIONS

This application claims priority from U.S. Provisional Application No. 62/810,950, filed on Feb. 26, 2019, and incorporated herein by reference in its entirety.

### BACKGROUND

Millimeter wave applications have emerged to address the need for higher bandwidth and data rates. The millimeter wave spectrum covers frequencies between 30 and 300 GHz and is able to reach data rates of 10 Gbits/s or more with wavelengths in the 1 to 10 mm range. The shorter wavelengths have distinct advantages, including better resolution, high frequency reuse and directed beamforming that are critical in wireless communications and autonomous driving applications. The shorter wavelengths are, however, susceptible to high atmospheric attenuation and have a limited range (just over a kilometer).

In many of these applications, phase shifters are needed to achieve a full range of phase shifts to direct beams to desired directions. Designing millimeter wave phase shifters is challenging as losses must be minimized in miniaturized circuits while providing phase shifts anywhere from 0 to 360°.

### BRIEF DESCRIPTION OF THE DRAWINGS

The present application may be more fully appreciated in connection with the following detailed description taken in conjunction with the accompanying drawings, which are not drawn to scale and in which like reference characters refer to like parts throughout, and wherein:

FIG. 1 is a schematic diagram of a switchable reflective phase shifter for millimeter wave applications in accordance with various implementations of the subject technology;

FIG. 2 is a schematic diagram of a switchable reflective phase shifter as in FIG. 1 and in accordance with various implementations of the subject technology;

FIG. 3 is a schematic diagram of a varactor based reflective phase shifter as in FIG. 2 and in accordance with various implementations of the subject technology;

FIG. 4 is a schematic diagram of a switchable phase network as in FIG. 2 and in accordance with various implementations of the subject technology;

FIG. 5 is a flowchart for generating a desired phase shift with a switchable reflective phase shifter as in FIG. 2 and in accordance with various implementations of the subject technology;

FIG. 6 illustrates example values for phase shifts, bias voltages and varactor control voltage for a switchable reflective phase shifter as in FIG. 2 and in accordance with various implementations of the subject technology;

FIG. 7 illustrates a MMIC layout for a switchable reflective phase shifter as in FIG. 2 and in accordance with various implementations of the subject technology;

FIG. 8 is a graph showing insertion loss across phase for a switchable reflective phase shifter as in FIG. 2 and in accordance with various implementations of the subject technology;

FIG. 9 is a graph showing phase shifts achieved by a switchable reflective phase shifter as in FIG. 2 and in accordance with various implementations of the subject technology;

FIG. 10 illustrates an example environment in which a beam steering radar system in an autonomous vehicle having a switchable reflective phase shifter is used to detect and identify objects in accordance with various implementations of the subject technology;

FIG. 11 is a schematic diagram of an autonomous driving system for an autonomous vehicle in accordance with various implementations of the subject technology;

FIG. 12 is a schematic diagram of a beam steering radar system as in FIG. 11 and in accordance with various implementations of the subject technology;

FIG. 13 is a flowchart for steering RF beams in a beam steering vehicle radar for object identification in accordance with various implementations of the subject technology; and

FIG. 14 illustrates an example 5G application using a switchable reflective phase shifter in accordance with various implementations of the subject technology.

### DETAILED DESCRIPTION

A Switchable Reflective Phase Shifter (“SRPS”) for millimeter wave applications is disclosed. The SRPS is capable of generating continuous phase shifts of anywhere from 0° to 360° with the use of a varactor based reflective phase shifter capable of operating in millimeter wave frequencies. The SRPS is designed in a robust topology with low amplitude variation over phase, minimized ESD effects and a small MMIC layout size that makes it desirable for many millimeter wave applications, such as wireless communications, ADAS, and autonomous driving.

In particular, the SRPS described herein enables fast scans of up to 360° of an entire environment in a fraction of time of current autonomous driving systems, and with improved performance, all-weather/all-condition detection, advanced decision-making and interaction with multiple vehicle sensors through sensor fusion. The examples described herein provide enhanced phase shifting of a transmitted RF signal to achieve transmission in the autonomous vehicle range, which in the US is approximately 77 GHz and has a 5 GHz range, specifically, from 76 GHz to 81 GHz. The examples described herein also reduce the computational complexity of a radar system and increase its transmission speed.

It is appreciated that, in the following description, numerous specific details are set forth to provide a thorough understanding of the examples. However, it is appreciated that the examples may be practiced without limitation to these specific details. In other instances, well-known methods and structures may not be described in detail to avoid unnecessarily obscuring the description of the examples. Also, the examples may be used in combination with each other.

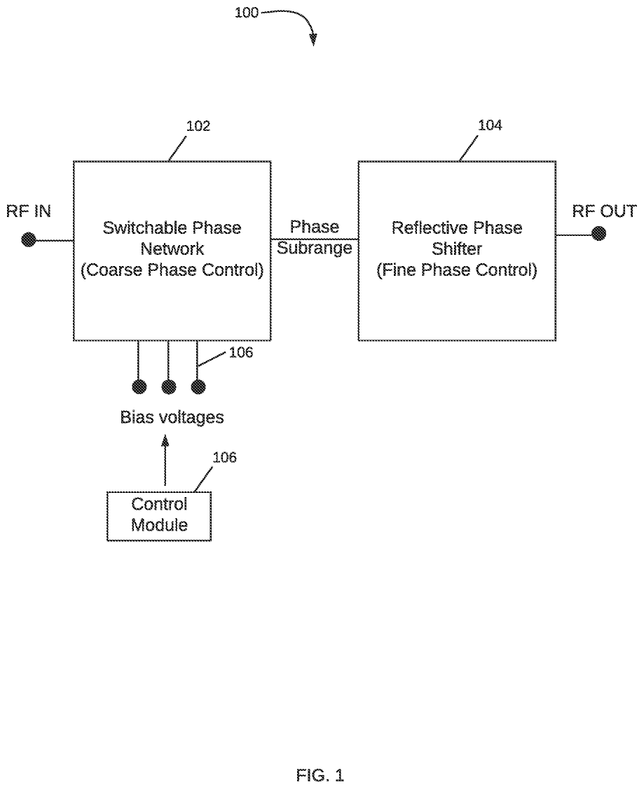

FIG. 1 is a schematic diagram of a SRPS for millimeter wave applications in accordance with various examples. SRPS 100 has two main circuits: switchable phase network 102 and reflective phase shifter 104. Switchable phase network 102 includes delay lines and switches to enable phase shifts in reflective phase shifter 104 in a set of phase subranges, such as, for example 90° phase subranges, 120° phase subranges, and so on. A set of bias voltages 106 is used to activate the switches in the switchable phase network 102. Each bias voltage activates a given switch and enables phase shifts in a given phase subrange. Reflective phase shifter 104 is designed to generate phase shifts in each subrange. In various examples, reflective phase shifter 104 is implemented with a set of varactors to achieve continuous phase shifts for a set of varactor control voltages.

A varactor is a variable capacitance diode whose capacitance varies with an applied varactor control or reverse bias voltage. By changing the value of the control voltage, the capacitance of the varactor is changed over a given range of values. The design of varactors for millimeter wave applications suffer from quality factor and tuning range limitations, with the quality factor falling well below desired levels. Varactors having a broad tuning range in the millimeter wave spectrum are therefore hard to achieve, thereby limiting their use in millimeter wave applications that may require a 360° phase shift to realize their full potential. An ideal varactor, i.e., a lossless non-linear reactance, has a given capacitance range of about 20 to 80 fF and no loss (Rs=0Ω). An ideal varactor can provide a phase shift in the range of about 52° to 126°. In various applications where a full 360° phase shift is desired, this phase shift is not sufficient.

SRPS 100 provides a solution to this limited phase shift range problem by introducing a distributed varactor network to generate any desired phase shift between 0° and 360°. Each desired phase shift is generated in response to a bias voltage provided by a control module 106. In a beam steering vehicle radar application, the control module 106 is a perception module that instructs a beam steering antenna to steer RF beams based on a detection and identification of an object. In a wireless communications application, the control module 106 acts to steer RF beams as desired to improve wireless coverage for users, such as users in non-line-of-sight regions.

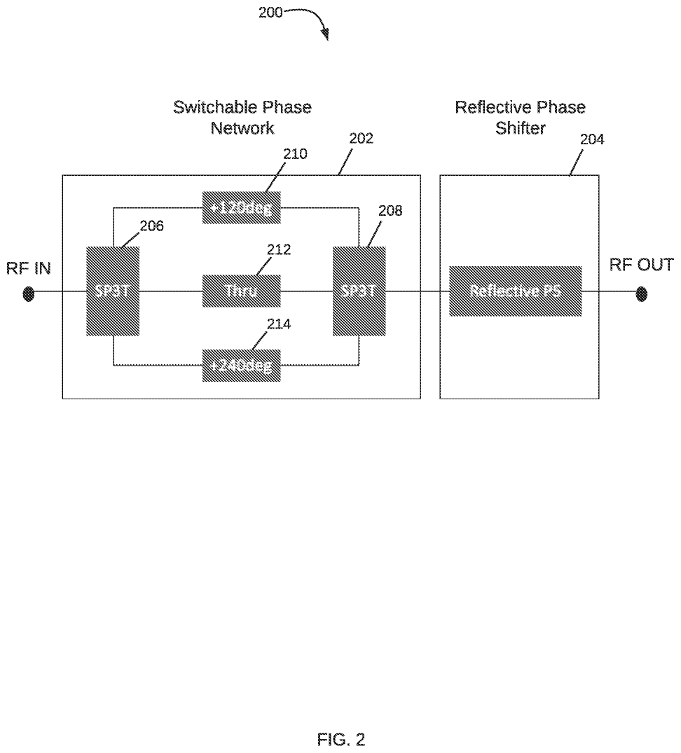

Attention is now directed to FIG. 2, which shows a schematic diagram of a switchable reflective phase shifter implemented as in FIG. 1 and in accordance with various examples. SRPS 200 is shown with switchable phase network 202 and reflective phase shifter 204. Switchable phase network 202 has two Single Pole, Three Throw (“SP3T”) switches 206-208 to enable three phase subranges in which the reflective phase shifter 204 can produce fine phase control. Phase subrange 210 is activated to generate phase shifts in reflective phase shifter 104 from 0 to 120°, phase subrange 212 is activated to generate phase shifts in reflective phase shifter 204 from 120° to 240°, and phase subrange 214 is activated to generate phase shifts in reflective phase shifter 204 from 240° to 360°. When a respective bias voltage is input to switchable phase network 202, a phase subrange is enabled for reflective phase shifter 204 to generate phase shifts within that phase subrange. For example, when a bias voltage corresponding to phase subrange 210 is input to switchable phase network 202, reflective phase shifter 204 is able to generate continuous phase shifts within that subrange of 0° to 120°.

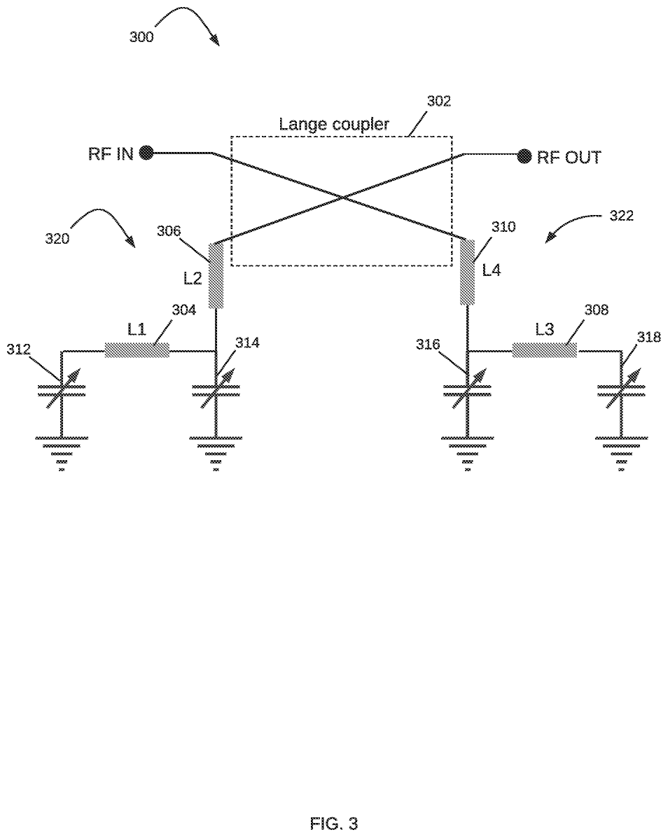

A schematic diagram of a varactor based reflective phase shifter 204 is shown in FIG. 3. Reflective phase shifter 300 is a distributed varactor network implemented with a Lange coupler 302, impedance lines 304-310, and varactors 312-318. The Lange coupler 302 divides an RF input signal into two signals that are 90° out of phase. The signals reflect from matched reflective loads 320-322 and combine in phase at the RF output. Impedance lines 304-310 can be, for example, transmission lines of a quarter of a wavelength (λ/4) or other such value. Each line 304-310 can be of a different or have the same length. The addition of the impedance lines 304-310 coupled to varactors 312-318 creates a purely capacitive or purely inductive circuit, depending on the varactors used. When an RF signal is input to the reflective phase shifter 300, the signal is distributed to the different lines 304-310 and is reflected back with an increased phase range. The phase range of each varactor 312-318 is controlled by a varactor control voltage (not shown).

Note that the reflective phase shifter 300 achieves a full 360° phase shift only if ideal varactors are used. Actual varactors designed for millimeter wave applications suffer from quality factor and tuning range limitations. The tuning range of a millimeter wave varactor is in reality much smaller than that of ideal varactors. In the case of millimeter wave varactors, reflective phase shifter 300 is able to generate phase shifts within a given phase subrange, such as phase shifts in a 120° phase subrange. A full phase shift of 360° can therefore be achieved with the SRPS design of FIGS. 1 and 2 with the addition of a switchable phase network to activate different phase subranges for the reflective phase shifter.

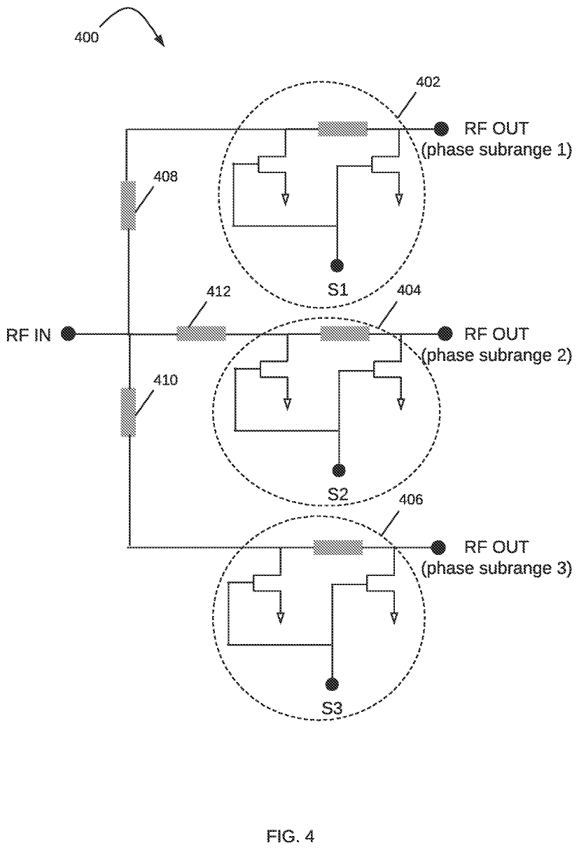

Referring now to FIG. 4, a schematic diagram of a switchable phase network as in FIG. 2 in accordance with various examples is described. Switchable phase network 400 is a S3PT switch having three circuit blocks 402-406 coupled to impedance lines 408-412. Each circuit block is activated by a respective bias voltage, e.g., circuit block 402 is activated with bias voltage S1, circuit block 404 is activated with bias voltage S2, and circuit block 406 is activated with bias voltage S3. The impedance lines 408-412 can be quarter wavelength lines or other such value such that the outputs of each circuit block is at a given phase subrange. Circuit block 402 can generate RF signals with phases within 0° to 120°, circuit block 404 can generate RF signals with phases within 120° to 240°, and circuit block 406 can generate RF signals with phases within 240° to 360°.

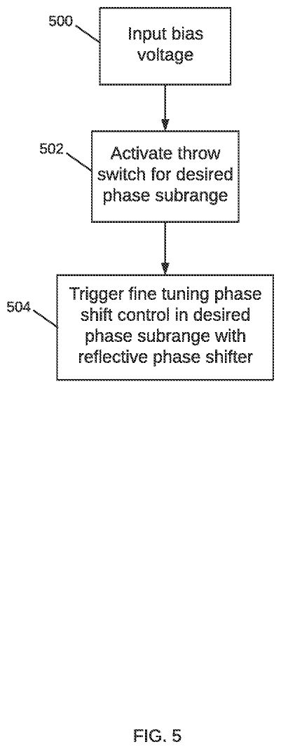

FIG. 5 shows a flowchart for generating a desired phase shift with a SRPS as in FIG. 2 and in accordance with various implementations of the subject technology. First, a bias voltage is input into the SRPS (500). The bias voltage activates a given throw switch (e.g., circuit blocks 402-406 in FIG. 4) to generate phase shifts in a given phase subrange (502). The throw switch activation then triggers fine tuning phase shift control in the desired phase subrange with the reflective phase shifter in the SRPS circuit (504).

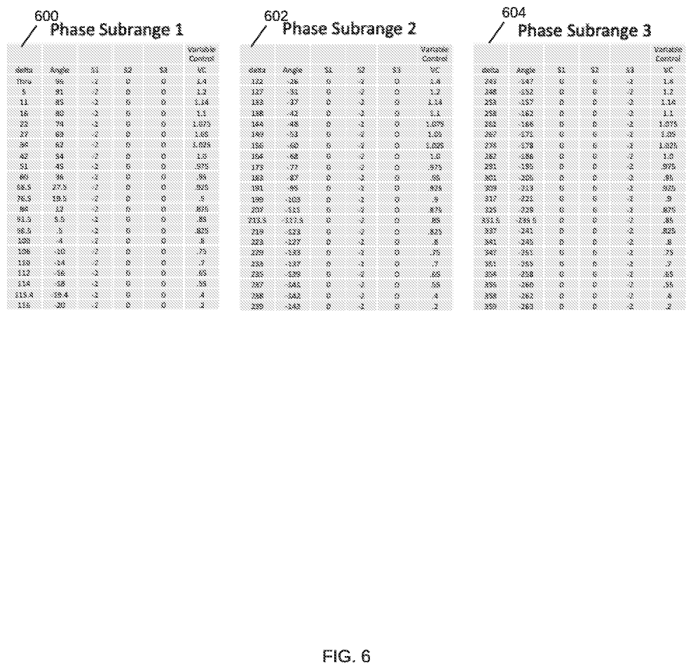

FIG. 6 illustrates example values for phase shifts, bias voltages and varactor control voltage for a SRPS as in FIG. 2 and in accordance with various implementations of the subject technology. Table 600 shows the delta and angle phase values within 0° to 120° that are achieved for bias voltage S1 and different varactor control voltages, table 602 lists the parameter values for a phase subrange within 120° to 240°, and table 604 lists the parameter values for a phase subrange within 240° to 360°. The results illustrated demonstrate the capacity of the SRPS described herein to indeed generate continuous phase shifts for full phase range of up to 360°. This enables beam steering in 5G and autonomous vehicle applications in the millimeter wave frequency range, satisfying the need for many applications.

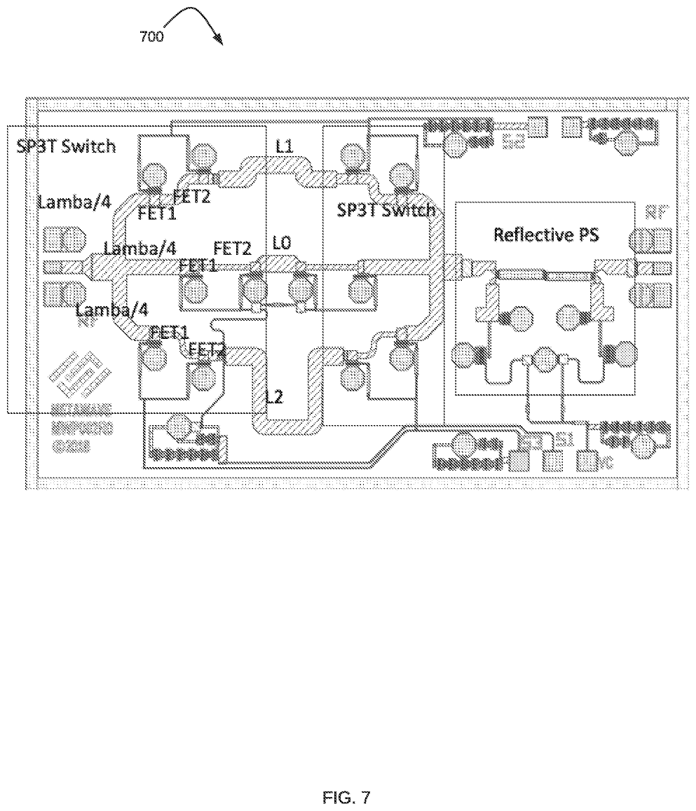

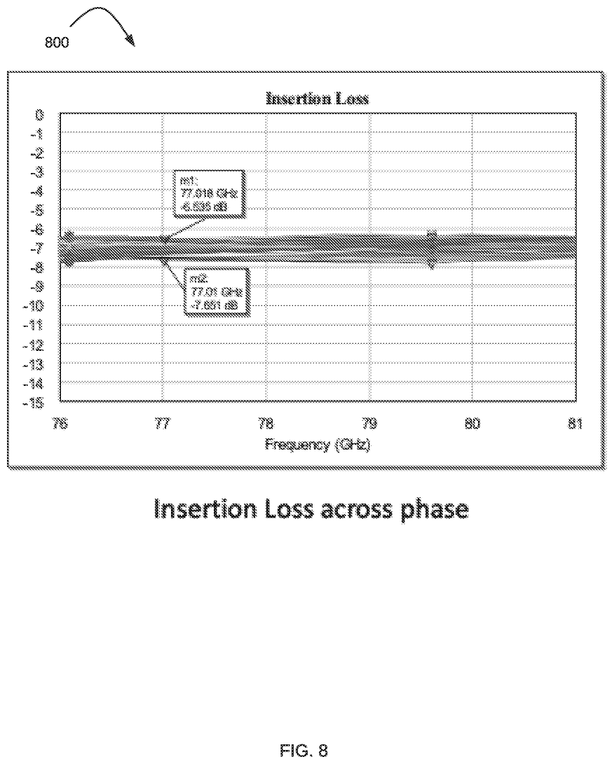

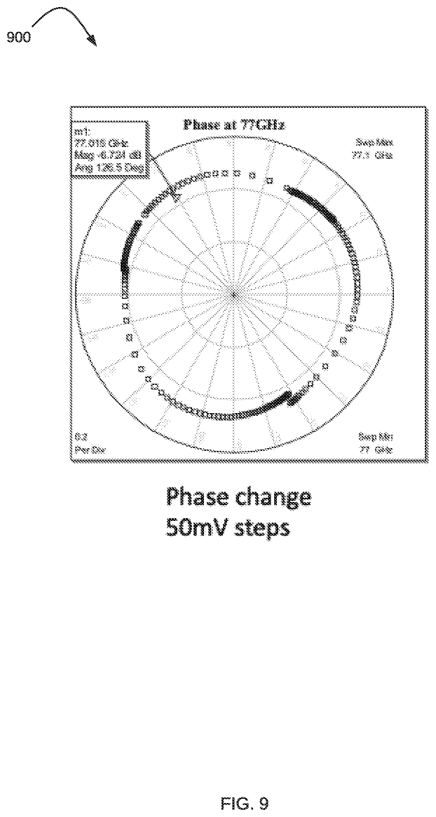

FIG. 7 illustrates an example MMIC layout for a SRPS in accordance with various implementations of the subject technology. MMIC 700 is achieved in a GaAs process in a circuit size of around 1.65 mm by 2.9 mm suitable for many millimeter wave applications. FIG. 8 is a graph 800 showing insertion loss across phase for SRPS 200. The insertion loss of SRPS 200 is controlled across frequencies and phases and stays around 6.5 dB. In FIG. 9, a graph 900 showing phase shifts achieved by SRPS 200 illustrates its full phase capability of up to 360°.

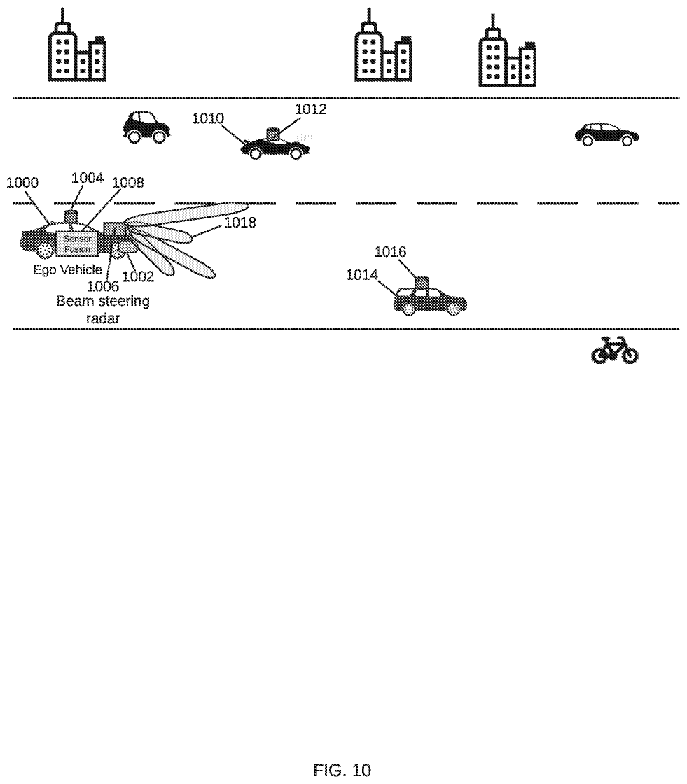

The SRPS described herein is applicable to many millimeter wave applications, including to beam steering radar applications in autonomous vehicles. Beam steering radars implemented with the SRPS described herein are capable of steering RF beams anywhere from 0° to 360° with the phase shifts produced by the SRPS. Attention is now directed to FIG. 10, which illustrates an example environment in which a beam steering radar system in an autonomous vehicle is used to detect and identify objects. Ego vehicle 1000 is an autonomous vehicle with a beam steering radar system 1006 for transmitting a radar signal to scan a FoV or specific area. The entire FoV or a portion of it can be scanned by a compilation of such transmission beams 1018, which may be in successive adjacent scan positions or in a specific or random order. Note that the term FoV is used herein in reference to the radar transmissions and does not imply an optical FoV with unobstructed views. The scan parameters may also indicate the time interval between these incremental transmission beams, as well as start and stop angle positions for a full or partial scan.

In various examples, the ego vehicle 1000 may also have other perception sensors, such as camera 1002 and lidar 1004. These perception sensors are not required for the ego vehicle 1000, but may be useful in augmenting the object detection capabilities of the beam steering radar system 1006. Camera sensor 1002 may be used to detect visible objects and conditions and to assist in the performance of various functions. The lidar sensor 1004 can also be used to detect objects and provide this information to adjust control of the vehicle. This information may include information such as congestion on a highway, road conditions, and other conditions that would impact the sensors, actions or operations of the vehicle. Camera sensors are currently used in Advanced Driver Assistance Systems (“ADAS”) to assist drivers in driving functions such as parking (e.g., in rear view cameras). Cameras are able to capture texture, color and contrast information at a high level of detail, but similar to the human eye, they are susceptible to adverse weather conditions and variations in lighting. Camera 1002 may have a high resolution but cannot resolve objects beyond 50 meters.

Lidar sensors typically measure the distance to an object by calculating the time taken by a pulse of light to travel to an object and back to the sensor. When positioned on top of a vehicle, a lidar sensor is able to provide a 360° 3D view of the surrounding environment. Other approaches may use several lidars at different locations around the vehicle to provide a4 full 360° view. However, lidar sensors such as lidar 1004 are still prohibitively expensive, bulky in size, sensitive to weather conditions and are limited to short ranges (typically <150-200 meters). Radars, on the other hand, have been used in vehicles for many years and operate in all-weather conditions. Radars also use far less processing than the other types of sensors and have the advantage of detecting objects behind obstacles and determining the speed of moving objects. When it comes to resolution, lidars' laser beams are focused on small areas, have a smaller wavelength than RF signals, and are able to achieve around 0.25 degrees of resolution.

In various examples and as described in more detail below, the beam steering radar system 1006 is capable of providing a 360° true 3D vision and human-like interpretation of the ego vehicle's path and surrounding environment. The radar system 1006 is capable of shaping and steering RF beams in all directions in a 360° FoV with a beam steering antenna module (having at least one beam steering antenna) and recognize objects quickly and with a high degree of accuracy over a long range of around 300 meters or more. The short range capabilities of camera 1002 and lidar 1004 along with the long range capabilities of radar 1006 enable a sensor fusion module 1008 in ego vehicle 1000 to enhance its object detection and identification.

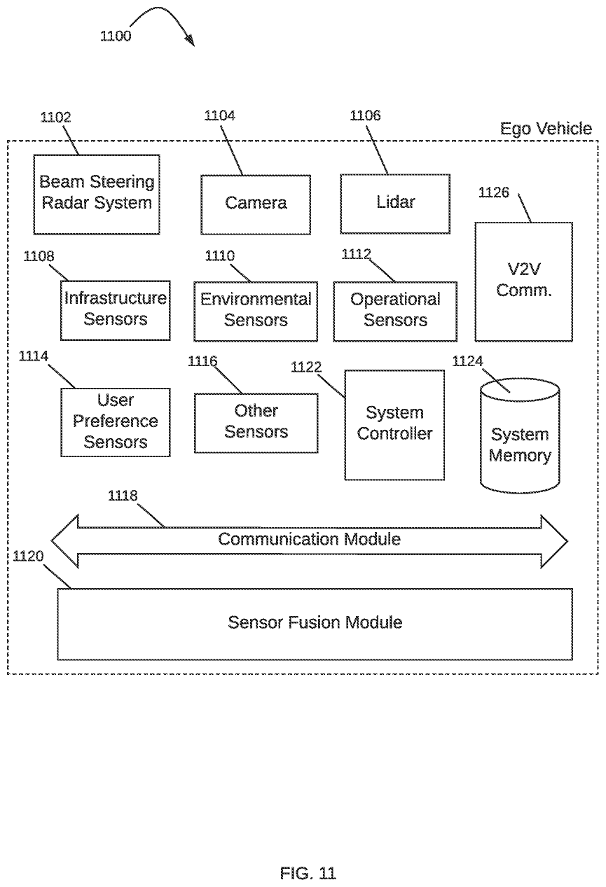

FIG. 11 illustrates a schematic diagram of an autonomous driving system for an ego vehicle in accordance with various examples. Autonomous driving system 1100 is a system for use in an ego vehicle that provides some or full automation of driving functions. The driving functions may include, for example, steering, accelerating, braking, and monitoring the surrounding environment and driving conditions to respond to events, such as changing lanes or speed when needed to avoid traffic, crossing pedestrians, animals, and so on. The autonomous driving system 1100 includes a beam steering radar system 1102 and other sensor systems such as camera 1104, lidar 1106, infrastructure sensors 1108, environmental sensors 1110, operational sensors 1112, user preference sensors 1114, and other sensors 1116. Autonomous driving system 1100 also includes a communications module 1118, a sensor fusion module 1120, a system controller 1122, a system memory 1124, and a V2V communications module 1126. It is appreciated that this configuration of autonomous driving system 1100 is an example configuration and not meant to be limiting to the specific structure illustrated in FIG. 11. Additional systems and modules not shown in FIG. 11 may be included in autonomous driving system 1100.

In various examples, beam steering radar system 1102 includes at least one beam steering antenna for providing dynamically controllable and steerable beams that can focus on one or multiple portions of a 360° FoV of the vehicle. The beams radiated from the beam steering antenna are reflected back from objects in the vehicle's path and surrounding environment and received and processed by the radar system 1102 to detect and identify the objects. Radar system 1102 includes a perception module that is trained to detect and identify objects and control the radar module as desired. Camera sensor 1104 and lidar 1106 may also be used to identify objects in the path and surrounding environment of the ego vehicle, albeit at a much lower range.

Infrastructure sensors 1108 may provide information from infrastructure while driving, such as from a smart road configuration, bill board information, traffic alerts and indicators, including traffic lights, stop signs, traffic warnings, and so forth. This is a growing area, and the uses and capabilities derived from this information are immense. Environmental sensors 1110 detect various conditions outside, such as temperature, humidity, fog, visibility, precipitation, among others. Operational sensors 1112 provide information about the functional operation of the vehicle. This may be tire pressure, fuel levels, brake wear, and so forth. The user preference sensors 1114 may be configured to detect conditions that are part of a user preference. This may be temperature adjustments, smart window shading, etc. Other sensors 1116 may include additional sensors for monitoring conditions in and around the vehicle.

In various examples, the sensor fusion module 1120 optimizes these various functions to provide an approximately comprehensive view of the vehicle and environments. Many types of sensors may be controlled by the sensor fusion module 1120. These sensors may coordinate with each other to share information and consider the impact of one control action on another system. In one example, in a congested driving condition, a noise detection module (not shown) may identify that there are multiple radar signals that may interfere with the vehicle. This information may be used by a perception module in radar 1202 to adjust the radar's scan parameters so as to avoid these other signals and minimize interference.

In another example, environmental sensor 1110 may detect that the weather is changing, and visibility is decreasing. In this situation, the sensor fusion module 1120 may determine to configure the other sensors to improve the ability of the vehicle to navigate in these new conditions. The configuration may include turning off camera or lidar sensors 1104-1106 or reducing the sampling rate of these visibility-based sensors. This effectively places reliance on the sensor(s) adapted for the current situation. In response, the perception module configures the radar 1102 for these conditions as well. For example, the radar 1102 may reduce the beam width to provide a more focused beam, and thus a finer sensing capability.

In various examples, the sensor fusion module 1120 may send a direct control to the antenna based on historical conditions and controls. The sensor fusion module 1120 may also use some of the sensors within system 1100 to act as feedback or calibration for the other sensors. In this way, an operational sensor 1112 may provide feedback to the perception module and/or the sensor fusion module 1120 to create templates, patterns and control scenarios. These are based on successful actions or may be based on poor results, where the sensor fusion module 1120 learns from past actions.

Data from sensors 1102-1116 may be combined in sensor fusion module 1120 to improve the target detection and identification performance of autonomous driving system 1000. Sensor fusion module 1120 may itself be controlled by system controller 1122, which may also interact with and control other modules and systems in the vehicle. For example, system controller 1122 may turn the different sensors 1102-1116 on and off as desired, or provide instructions to the vehicle to stop upon identifying a driving hazard (e.g., deer, pedestrian, cyclist, or another vehicle suddenly appearing in the vehicle's path, flying debris, etc.)

All modules and systems in autonomous driving system 1100 communicate with each other through communication module 1118. Autonomous driving system 1100 also includes system memory 1124, which may store information and data (e.g., static and dynamic data) used for operation of system 1100 and the ego vehicle using system 1100. V2V communications module 1126 is used for communication with other vehicles. The V2V communications module 1126 may also include information from other vehicles that is invisible to the user, driver, or rider of the vehicle, and may help vehicles coordinate to avoid an accident.

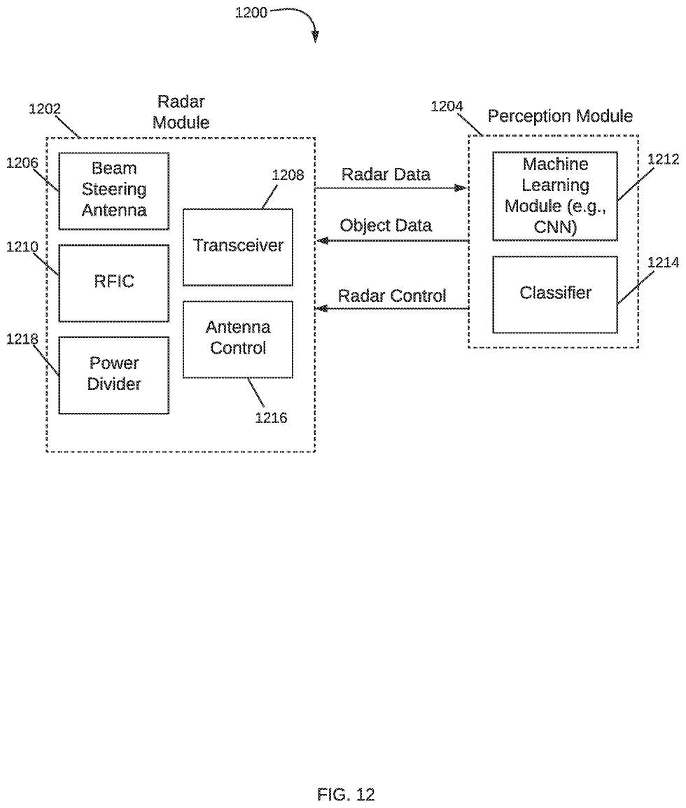

FIG. 12 illustrates a schematic diagram of a beam steering radar system as in FIG. 2 and in accordance with various implementations of the subject technology. Beam steering radar system 1200 is a “digital eye” with true 3D vision and capable of a human-like interpretation of the world. The “digital eye” and human-like interpretation capabilities are provided by two main modules: radar module 1202 and a perception module 1204. The radar module 1202 includes at least one beam steering antenna 1206 for providing dynamically controllable and steerable beams that can focus on one or multiple portions of a 360° FoV of an autonomous ego vehicle. It is noted that current beam steering antenna implementations are able to steer beams of up to 120°−180° FoV. Multiple beam steering antennas may be needed to provide steerability to reach the full 360° FoV.

In various examples, the beam steering antenna 1206 is integrated with RFIC 1210 including the SRPS described herein for providing RF signals at multiple steering angles. The antenna may be a meta-structure antenna, a phased array antenna, or any other antenna capable of radiating RF signals in millimeter wave frequencies. A meta-structure, as generally defined herein, is an engineered structure capable of controlling and manipulating incident radiation at a desired direction based on its geometry. The meta-structure antenna may include various structures and layers, including, for example, a feed or power division layer 1218 to divide power and provide impedance matching, an RF circuit layer with RFIC 1210 to provide steering angle control and other functions, and a meta-structure antenna layer with multiple microstrips, gaps, patches, vias, and so forth. The meta-structure layer may include a metamaterial layer. Various configurations, shapes, designs and dimensions of the beam steering antenna 1206 may be used to implement specific designs and meet specific constraints.

Radar control is provided in part by the perception module 1204, which acts as control module 106 of FIG. 1. Radar data generated by the radar module 1202 is provided to the perception module 1204 for object detection and identification. The radar data is acquired by the transceiver 1208, which has a radar chipset capable of generating the RF signals radiated by the beam steering antenna 1206 and receiving the reflections of these RF signals. Object detection and identification in perception module 1204 is performed in a Machine Learning Module (“MLM”) 1212 and in a classifier 1214. Upon identifying objects in the FoV of the vehicle, the perception module 1204 provides object data and control instructions to antenna control 1216 in radar module 1202 for adjusting the beam steering and beam characteristics as needed. In various implementations, the control instructions include instructions to provide different phase shifts by adjusting bias voltages input into the SRPS in RFIC 1210.

The MLM 1212, in various examples, implements a CNN that, in various examples, is a fully convolutional neural network (“FCN”) with three stacked convolutional layers from input to output (additional layers may also be included in the CNN). Each of these layers also performs the rectified linear activation function and batch normalization as a substitute for traditional L2 regularization and each layer has 64 filters. Unlike many FCNs, the data is not compressed as it propagates through the network because the size of the input is relatively small and runtime requirements are satisfied without compression. In various examples, the CNN may be trained with raw radar data, synthetic radar data, lidar data and then retrained with radar data, and so on. Multiple training options may be implemented for training the CNN to achieve a good object detection and identification performance.

The classifier 1214 may also include a CNN or other object classifier to enhance the object identification capabilities of perception module 1204 with the use of the velocity information and micro-doppler signatures in the radar data acquired by the radar module 1202. When an object is moving slowly, or is moving outside a road lane, then it most likely is not a motorized vehicle, but rather a person, animal, cyclist and so forth. Similarly, when one object is moving at a high speed, but lower than the average speed of other vehicles on a highway, the classifier 1214 uses this velocity information to determine if that vehicle is a truck or another object which tends to move more slowly. The location of the object, such as in the far-right lane of a highway in some countries (e.g., in the United States of America) may indicate a slower-moving type vehicle. If the movement of the object does not follow the path of a road, then the object may be an animal, such as a deer, running across the road. All of this information may be determined from a variety of sensors and information available to the vehicle, including information provided from weather and traffic services, as well as from other vehicles or the environment itself, such as smart roads and smart traffic signs.

Note that velocity information is unique to radar sensors. Radar data is in a multi-dimensional format having data tuples of the form (rᵢ, θᵢ, ϕᵢ, Iᵢ, vᵢ), where rᵢ, θᵢ, ϕᵢ represent the location coordinates of an object with rᵢ denoting the range or distance between the radar system 300 and the object along its line of sight, θᵢ is the azimuthal angle, and ϕᵢ is elevation angle, Iᵢ is the intensity or reflectivity indicating the amount of transmitted power returned to the transceiver 1208 and vᵢ is the speed between the radar system 1200 and the object along its line of sight. The location and velocity information provided by the perception module 1204 to the radar module 1202 enables the antenna control 1210 to adjust its parameters accordingly.

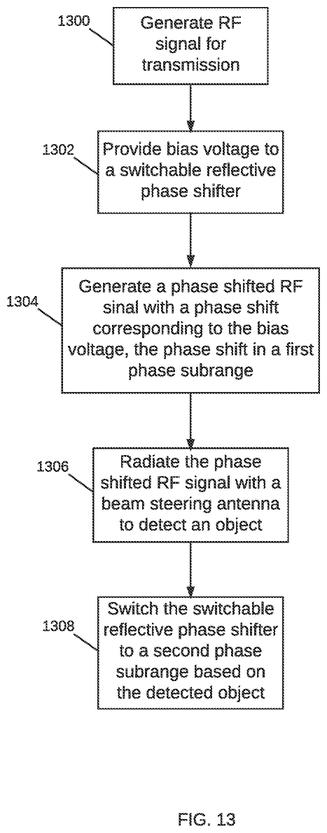

FIG. 13 illustrates a flowchart for steering RF beams in a beam steering vehicle radar for object detection and identification as in beam steering vehicle radar 1200 of FIG. 12. First, an RF signal is generated for transmission at a transceiver (1300). A bias voltage is provided to a switchable reflective phase shifter in an RFIC in the beam steering vehicle radar (1302). Note that there may be multiple switchable reflective phase shifters in an RFIC and multiple RFICs in the beam steering vehicle radar, such as, for example, an RFIC coupled to multiple antenna elements. Each switchable reflective phase shifter generates a phase shift in a first phase subrange corresponding to the bias voltage for the transceiver to provide a phase shifted RF signal to the beam steering antenna, e.g., beam steering antenna 1206 (1304). The beam steering antenna then radiates the phase shifted RF signal to detect an object (1306). The switchable reflective phase shifter is then switched to a second phase subrange based on the detected object to steer the beam to another direction (1308). This could be in response to the object moving to another location on the road or another such example. The SRPS enables an ego vehicle to steer beams to any desired direction for object detection at both short and long ranges.

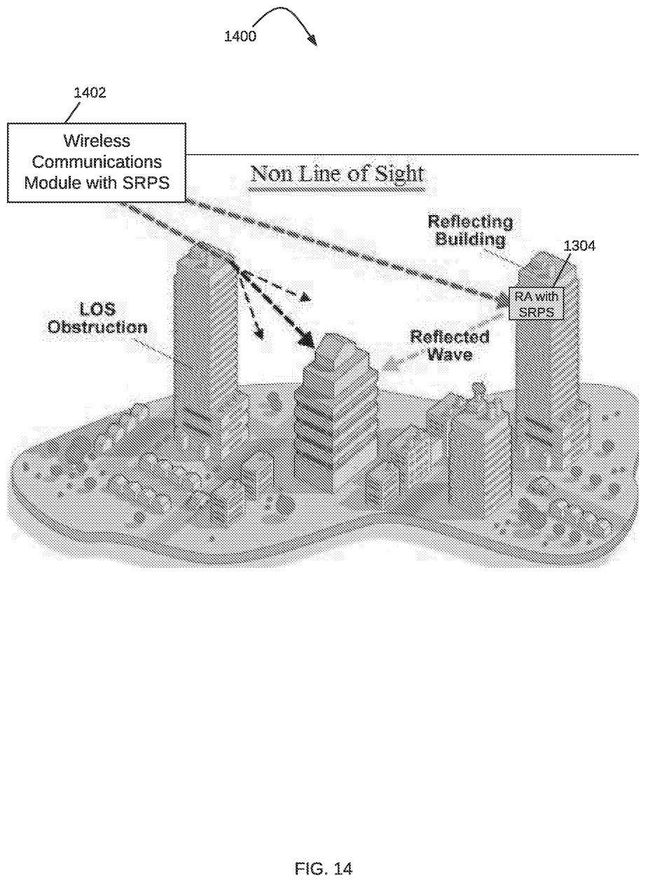

The SRPS described herein above can also be implemented in 5G applications, as illustrated in FIG. 14. In this application, a wireless communications module 1402 (e.g., a base station) incorporates a SRPS as described herein (e.g., SRPS 200 of FIG. 2) to transmit and receive RF beams. For example, an SRPS implemented in a wireless transceiver in module 1402 is able to steer RF beams radiated from the wireless module 1402 to any direction. During a receive operation, the SRPS may be used to align received RF beams that arrive at different times at each radiating element of a receive antenna in module 1402. In another example, an SRPS implemented in an active reflectarray module 1404 reflects RF beams transmitted from wireless communications module 1402 to any direction to reach users in non-line-of-sight areas. The desired direction is provided by a control module coupled to the reflectarray module 1404 and in response to conditions in the environment 1400 that may affect wireless coverage to users.

It is appreciated that the previous description of the disclosed examples is provided to enable any person skilled in the art to make or use the present disclosure. Various modifications to these examples will be readily apparent to those skilled in the art, and the m spirit or scope of the disclosure. Thus, the present disclosure is not intended to be limited to the examples shown herein but is to be accorded the widest scope consistent with the principles and novel features disclosed herein.

As used herein, the phrase “at least one of” preceding a series of items, with the terms “and” or “or” to separate any of the items, modifies the list as a whole, rather than each member of the list (i.e., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C. Furthermore, to the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. Moreover, the separation of various system components in the aspects described above should not be understood as requiring such separation in all aspects, and it should be understood that the described program components and systems can generally be integrated together in a single hardware product or packaged into multiple hardware products. Other variations are within the scope of the following claim.

What is claimed is:

1. A switchable reflective phase shifter, comprising:
a switchable phase shift network comprising a plurality of switches to activate a plurality of phase subranges in response to a plurality of bias voltages provided by a control module; and
a reflective phase shifter to generate phase shifts in a given phase subrange activated by a given switch in the plurality of switches.

2. The switchable reflective phase shifter of claim 1, wherein the plurality of switches comprises a plurality of Single Pole, Three Throw (“SP3T”) switches triggered by the plurality of bias voltages provided by the control module.

3. The switchable reflective phase shifter of claim 2, wherein the plurality of SP3T switches comprises a first and a second SP3T switch coupled to a delay line of 120° and a delay line of 240°.

4. The switchable reflective phase shifter of claim 1, wherein the plurality of phase subranges comprises a first phase subrange from 0° to 120°, a second phase subrange from 120° to 240°, and a third phase subrange from 240° to 360°.

5. The switchable reflective phase shifter of claim 1, wherein the reflective phase shifter comprises a distributed varactor network implemented with a Lange coupler and a plurality of impedance lines.

6. The switchable reflective phase shifter of claim 5, wherein the Lange coupler is coupled to a first impedance line coupled to a first reflective load and a second impedance line coupled to a second reflective load.

7. The switchable reflective phase shifter of claim 6, wherein the first reflective load comprises a first and a second varactor coupled to a third impedance line.

8. The switchable reflective phase shifter of claim 6, wherein the second reflective load comprises a third and a fourth varactor coupled to a fourth impedance line.

9. The switchable reflective phase shifter of claim 5, wherein the reflective phase shifter reflects an RF signal distributed to the plurality of impedance lines with an increased phase range.

10. A beam steering vehicle radar for object identification, comprising:
a radar module comprising at least one beam steering antenna and at least one RFIC implemented with a switchable reflective phase shifter to steer RF beams across a field-of-view and receive reflections of the steered RF beams; and
a perception module to receive radar data corresponding to the reflections of the steered RF beams and generate control instructions to adjust a steering of the RF beams.

11. The beam steering vehicle radar of claim 10, wherein the at least one beam steering antenna comprises a meta-structure antenna.

12. The beam steering vehicle radar of claim 10, wherein the radar module further comprises a transceiver to generate RF signals to be radiated as RF beams by the at least one beam steering antenna and to generate the radar data from the received reflections of the steered RF beams.

13. The beam steering vehicle radar of claim 10, wherein the switchable reflective phase shifter comprises a switchable phase shift network having a plurality of switches to activate a plurality of phase subranges based on a plurality of bias voltages and a reflective phase shifter to generate phase shifts in a given phase subrange activated by a given switch in the plurality of switches.

14. The beam steering vehicle radar of claim 13, wherein the reflective phase shifter comprises a distributed varactor network implemented with a Lange coupler and a plurality of impedance lines.

15. The beam steering vehicle radar of claim 14, wherein the reflective phase shifter reflects an RF signal distributed to the plurality of impedance lines with an increased phase range.

16. The beam steering vehicle radar of claim 13, wherein the control instructions comprise instructions to adjust the plurality of bias voltages.

17. The beam steering vehicle radar of claim 10, wherein the perception module comprises a machine learning module to detect and identify objects from the radar data.

18. The beam steering vehicle radar of claim 17, wherein the control data is generated based on the detection and identification of objects from the radar data.

19. A method for steering RF beams in a beam steering vehicle radar for object detection and identification, comprising:
generating an RF signal for transmission;
providing a bias voltage to a switchable reflective phase shifter in the beam steering vehicle radar;
generating a phase shifted RF signal with a phase shift corresponding to the bias voltage, the phase shift in a first phase subrange;
radiating the phase shifted RF signal with a beam steering antenna to detect an object; and
switching the switchable reflective phase shifter to a second phase subrange based on the detected object.

20. The method of claim 19, further comprising providing control instructions to the beam steering vehicle radar to switch the switchable reflective phase shifter based on object detection data generated by a perception module upon detecting the object from a reflection of the phase shifted RF signal.
